(19) United States
(12) Patent Application Publication
(10) Pub. No.: US 2023/0200038 A1
(43) Pub. Date: Jun. 22, 2023

(54) ELECTRONIC COMPONENT INSPECTION APPARATUS AND ELECTRONIC COMPONENT MOUNTING APPARATUS USING THE SAME

(71) Applicant: Samsung Electronics Co., Ltd., Suwon-si (KR)

(72) Inventors: Daeseo PARK, Suwon-si (KR); Gukjong CHOI, Cheonan-si (KR); Ohseok KWON, Hwaseong-si (KR); Haegu LEE, Asan-si (KR)

(73) Assignee: Samsung Electronics Co., Ltd., Suwon-si, Gyeonggi-do (KR)

(21) Appl. No.: 17/959,721

(22) Filed: Oct. 4, 2022

(30) Foreign Application Priority Data
Dec. 21, 2021 (KR) 10-2021-0183824

(51) Int. Cl. H05K 13/08; H04N 5/247; G06T 7/70; G06T 7/00

(52) U.S. Cl. CPC H05K 13/0812; H05K 13/0813; H04N 5/247; G06T 7/70; G06T 7/001; G06T 2207/30141

(57) ABSTRACT

An electronic component mounting apparatus includes: a transfer unit picking up an upper surface of a light emitting device package having a front surface on which a light emitting diode chip is disposed, and transferring the light emitting device package to a printed circuit board, a light source unit disposed on a transfer path of the light emitting device package, and irradiating measurement light onto the front surface of the light emitting device package, a camera capturing an image of the light emitting device package to which the measurement light is irradiated, and a control unit image-processing the image to identify excitation light, emitted when the measurement light is excited from the light emitting diode chip, in the image, and controlling the transfer unit to mount the light emitting device package on the printed circuit board when identifying the excitation light.

### CROSS-REFERENCE TO RELATED APPLICATION(S)

This application claims the benefit under 35 USC 119(a) of Korean Patent Application No. 10-2021-0183824 filed on Dec. 21, 2021 in the Korean Intellectual Property Office, the entire disclosure of which is incorporated herein by reference for all purposes.

### BACKGROUND

The present inventive concepts relate to an electronic component inspection apparatus and an electronic component mounting apparatus using the same.

Light emitting device packages have been known as a next-generation light sources having advantages such as a long lifespan, low power consumption, fast response speeds and the like, when compared to conventional light sources. For example, the light emitting device package has been widely used as a display apparatus externally displaying signals of various electronic apparatuses. The plurality of light emitting device packages which emit light of different colors may be mounted in one electronic apparatus. However, colors of the light emitted from the light emitting device packages may not be checked before power is applied to the light emitting device packages, and types of the light emitting device packages may also be hard to distinguish by an appearance of the light emitting device packages due to the significantly small size thereof. Therefore, research has been conducted on a way to check that the light emitting device package emitting light of a different color before the light emitting device package is mounted on the electronic apparatus and/or power is applied to the electronic apparatus, for example, when light emitting device packages of the different colors are mixed with each other in a production process.

### SUMMARY

Example embodiments provide an electronic component inspection apparatus which may identify a type of light emitting device package.

Example embodiments provide an electronic component mounting apparatus which may identify a type of light emitting device package before mounting the light emitting device package on an electronic apparatus.

According to example embodiments, an electronic component mounting apparatus includes: a transfer unit configured to transfer a light emitting device package to a printed circuit board; a light source unit on a transfer path of the light emitting device package and configured to emit a measurement light of a first wavelength to a light emitting diode chip on the light emitting device package such that the light emitting diode chip emits excitation light of a second wavelength, longer than the first wavelength, when the light emitting device package is suitable; a first camera on the transfer path of the light emitting device package and configured to capture an image of the light emitting device package; and a control unit configured to determinine whether the light emitting device package is suitable or unsuitable based on whether the excitation light is captured in the image, and to control the transfer unit to mount the light emitting device package on the printed circuit board when the light emitting device package is determined to be suitable.

According to example embodiments, an electronic component mounting apparatus includes: a transfer unit configured to attach to an upper surface of a light emitting device package, and to transfer the light emitting device package to a printed circuit board; a light source unit on a transfer path of the light emitting device package, and configured to irradiate measurement light towards a light emitting diode chip on a front surface of the light emitting device package such that the light emitting diode chip emits excitation light when the light emitting device package is suitable; a camera configured to capture an image of the light emitting device package; and a control unit configured to process the image to identify excitation light in the image and to control the transfer unit to mount the light emitting device package on the printed circuit board when the excitation light is identified.

According to example embodiments, an electronic component inspection apparatus includes: a light source unit on a transfer path on which a light emitting device package is picked up and transferred, the light source unit configured to irradiate measurement light onto a front surface of the light emitting device package; a camera configured to caputure an image of the light emitting device package; and a control unit image-configured to process the image to identify excitation light, emitted from a light emitting diode chip on the front surface of the light emitting device when the light emitting diode chip is excited from the measurement light, and determining whether the light emitting device package is suitable or unsuitable based on an identification result.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a view schematically illustrating an electronic component mounting apparatus according to some example embodiments of the present inventive concepts;

FIG. 2 is a schematic block diagram of the electronic component mounting apparatus according to some example embodiments of the present inventive concepts;

FIG. 3 is a perspective view of a light emitting device package mounted by the electronic component mounting apparatus according to some example embodiments of the present inventive concepts;

FIG. 4 is a side view of a light emitting diode chip employed in the light emitting device package of FIG. 3;

FIG. 5 is a graph showing measurement lights respectively irradiated to light emitting diode chips having different colors of emitted light and excitation lights emitted by the light emitting diode chips;

FIG. 6A is a front image of a light emitting device package emitting the excitation light when the measurement light is irradiated thereto;

FIG. 6B is a front image of a light emitting device package emitting no excitation light when the measurement light is irradiated thereto;

FIG. 7 is a view schematically illustrating an electronic component mounting apparatus according to some example embodiments of the present inventive concepts;

FIG. 8A is a side image of the light emitting device package emitting excitation light when the measurement light is irradiated thereto;

FIG. 8B is a side image of the light emitting device package emitting no excitation light when the measurement light is irradiated thereto; and

FIG. 9 is a flowchart schematically illustrating an electronic component mounting method according to some example embodiments of the present inventive concepts.

### DETAILED DESCRIPTION

Hereinafter, example embodiments will be described with reference to the accompanying drawings.

Spatially relative terms, such as “lower,” “upper,” “front,” and/or the like may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

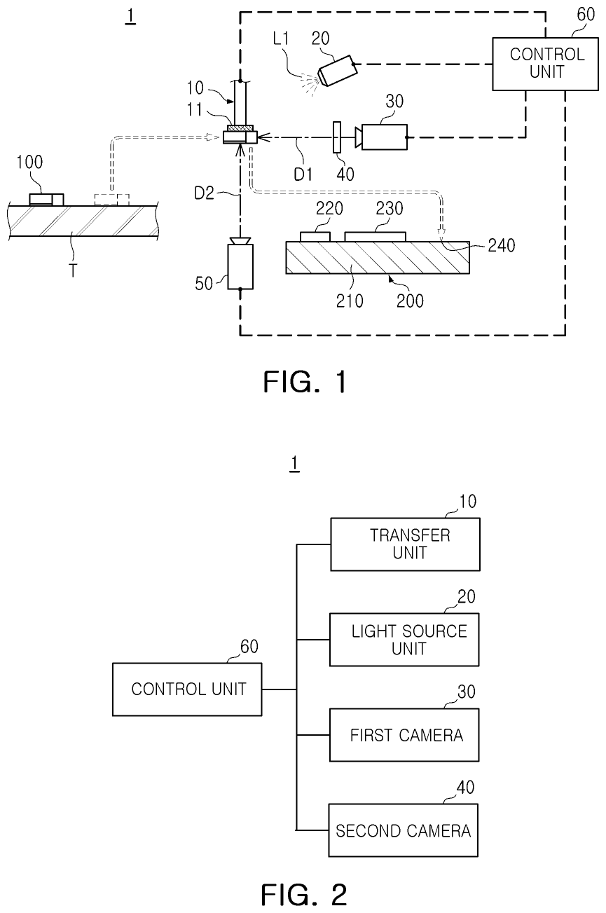

FIG. 1 is a view schematically illustrating an electronic component mounting apparatus according to some example embodiments of the present inventive concepts; and FIG. 2 is a schematic block diagram of the electronic component mounting apparatus according to some example embodiments of the present inventive concepts.

Referring to FIGS. 1 and 2, an electronic component mounting apparatus 1 may include a transfer unit 10, a light source unit 20, a first camera 30, a second camera 50 and a control unit 60. Components of the electronic component mounting apparatus 1 other than the transfer unit 10 may be understood as those of an electronic component inspection apparatus. The components of the electronic component mounting apparatus 1 other than the transfer unit 10 are the same as those of the electronic component inspection apparatus, and a separate description is thus omitted.

The transfer unit 10 may pick up a light emitting device package 100 which is a transfer object and mount the same on an electronic apparatus 200. The transfer unit 10 may, for example, include a robotic arm and a picker 11 picking up the light emitting device package 100. The picker 11 may be (and/or employ), for example, mechanical, pneumatic, electromagnetic manipulation, and/or the like to transfer the light emitting device package 100. The light emitting device package 100 may have a shape of a reel (e.g., by including a plurality of the light emitting device packages 100 attached to a tape T). The transfer unit 10 may pick up the light emitting device package 100, separate the light emitting device package from the tape T, transfer the separated light emitting device package 100 to the electronic apparatus 200, and mount the light emitting device package on a mounting position 240.

The electronic apparatus 200 may include a printed circuit board 210 having the mounting position 240 on which the light emitting device package 100 is mounted. The printed circuit board 210 may be provided in a state in which various types of semiconductor chips 220 and 230 are pre-mounted thereon. For example, the semiconductor chips 220 and 230 may include a processor and/or memory and/or may include electrical components such as at least one of transistors, resistors, capacitors, etc. and/or electrical components such as logic gates including at least one of AND gates, OR gates, NAND gates, NOR gates, XOR gates, etc.

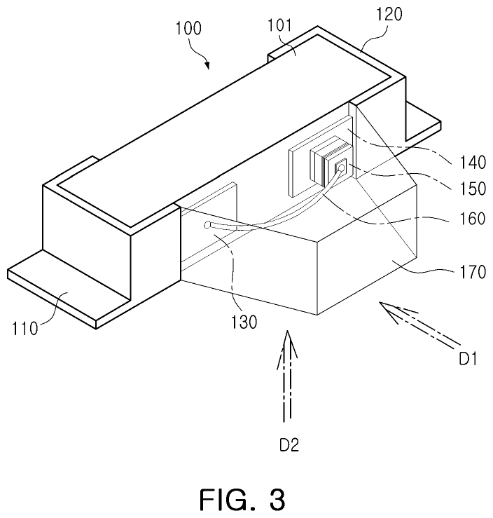

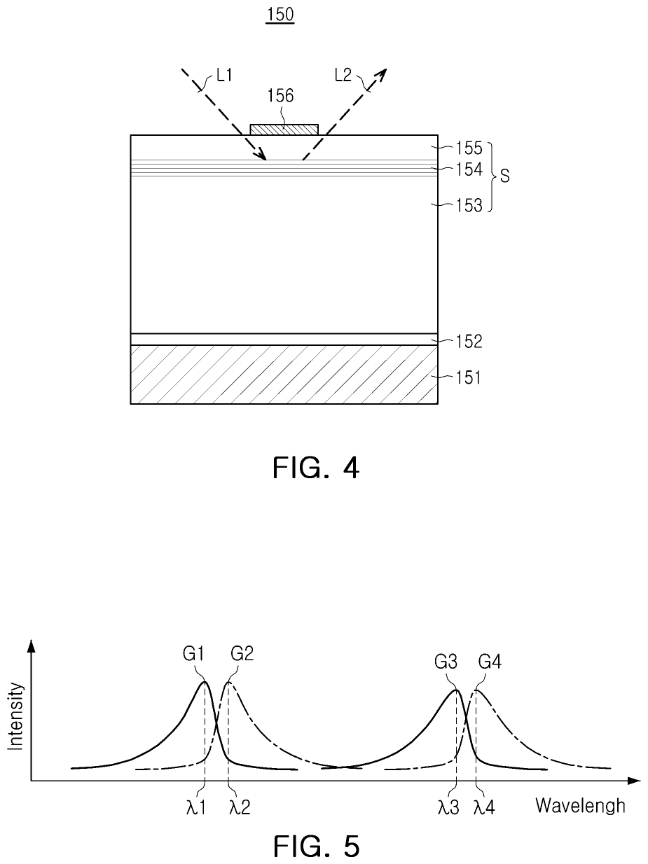

The light emitting device package 100, picked up by the transfer unit 10, according to some example embodiments is described with reference to FIGS. 3 and 4. FIG. 3 is a perspective view of the light emitting device package mounted by the electronic component mounting apparatus according to some example embodiments of the present inventive concepts; and FIG. 4 is a side view of a light emitting diode chip employed in the light emitting device package of FIG. 3.

Referring to FIG. 3, an upper surface of the light emitting device package 100 may be an attachment surface to which a picker 11 of the transfer unit 10 is attached, and a lower surface of the light emitting device package 100 may be a mounting surface which is mounted on the electronic apparatus 200.

The light emitting device package 100 may include a body 101, first and second lead frames 110 and 120, first and second electrode pads 130 and 140, a light emitting diode (LED) chip 150 and a light-transmitting encapsulation 170.

The body 101 may be formed by molding an insulating resin, and the first and second lead frames 110 and 120 may respectively be disposed on both sides of the body 101. The first and second electrode pads 130 and 140 may be electrically connected to the first and second lead frames 110 and 120, respectively, and may be disposed on a front surface of the body 101. The light emitting diode chip 150 may be mounted on the second electrode pad 140 and may be connected to the first electrode pad 130 through a wire 160. The light-transmitting encapsulation 170 covering the first and second electrode pads 130 and 140 and the light emitting diode chip 150 may be disposed on the front surface of the body 101.

The light emitting diode chip 150 may emit monochromatic light when power is applied thereto through the first and second electrode pads 130 and 140. For example, the monochromatic light may be within the visible light spectrum and/or the light emitting diode chip 150 may be any one of a red light emitting diode chip, a green light emitting diode chip, a blue light emitting diode chip, a yellow light emitting diode chip, and/or the like. The description describes an example of the light emitting diode chip 150 in detail with reference to FIG. 4.

Referring to FIG. 4, the light emitting diode chip 150 may include a light emitting structure S disposed on a support substrate 151 and an electrode 156 disposed on an upper surface of the light emitting structure S. The light emitting structure S may include a second conductivity-type semiconductor layer 153, an active layer 154 and a first conductivity-type semiconductor layer 155, which are sequentially disposed on the support substrate 151.

The support substrate 151 may be a substrate made of a material having conductivity or an insulating substrate having an electrode structure such as a conductive via connected to the support substrate 151 in a vertical direction. The support substrate 151 may serve to support the light emitting structure S and/or serve as a second electrode applying power to the second conductivity-type semiconductor layer 153. The support substrate 151 may be attached to the light emitting structure S through a conductive adhesive layer 152. The conductive adhesive layer 152 is provided to further strengthen the contact between the second conductivity-type semiconductor layer 153 and the support substrate 151, and may use an eutectic metal such as silver (Ag) paste, silver/germanium (Au/Ge), silver/indium (Au/In), silver/tin (Au/Sn), lead/tin (Pb/Sn), and/or the like.

The light emitting structure S may include the first and second conductivity-type semiconductor layers 155 and 153 and the active layer 154. In some example embodiments, the first conductivity-type semiconductor layer 155 may be an n-type semiconductor such as an n-type gallium nitride (GaN) and/or a nitride semiconductor satisfying InₓAl_{y}Ga_{1-x-y}N (0≤x<1, 0≤y<1, 0≤x+y<1). The first conductivity-type semiconductor layer 155 may include an n-type impurity, which may be silicon (Si). The second conductivity-type semiconductor layer 153 may be a p-type semiconductor, e.g., a p-type nitride semiconductor satisfying InₓAl_{y}Ga_{1-x-y}N (0≤x<1, 0≤y<1, 0≤x+y<1), and/or may include a p-type impurity (e.g., magnesium (Mg)). For example, the second conductivity-type semiconductor layer 153 may have a single-layer structure or may have a multi-layer structure including different compositions as in this example.

The active layer 154 may have a multi-quantum well (MQW) structure in which a quantum well layer and a quantum barrier layer are alternately stacked on each other. For example, the quantum well layer and the quantum barrier layer may have different compositions of the p-type semiconductor (e.g., InₓAl_{y}Ga_{1-x-y}N (0≤x≤1, 0≤y≤1, 0≤x+y≤1)). For example, the quantum well layer may be InₓGa₁₋ₓN(0<x≤1), and the quantum barrier layer may be gallium nitride (GaN) and/or aluminum gallium nitride (AlGaN). The quantum well layer and the quantum barrier layer may each have a thickness in a range of 1 nm to 50 nm. However, the example embodiments are not limited thereto. For example, the active layer 154 is not limited to the multi-quantum well structure and may have a single quantum well structure.

The active layer 154 having such a structure may emit light of a specific wavelength band, for example, red, green, blue, or yellow light when power is applied to the light emitting diode chip 150. In addition, even when no power is applied to the light emitting diode chip 150, the active layer 154 may become excited when light (hereinafter, ‘measurement light L1’) of a specific wavelength is irradiated thereto and emit excitation light L2.

The excitation light L2 may be light of and/or included in the same wavelength band as that of light which is emitted when power is applied to the active layer 154, and/or have a longer wavelength than that of the ‘measurement light L1’. For example, the active layer 154 may have a stokes shift characteristic in which the excitation light L2 having a longer wavelength than a specific (e.g., of predetermined or otherwise determined wavelength) is emitted when light of the specific wavelength is irradiated thereto.

The wavelength of the ‘measurement light L1’ from which the excitation light L2 may be emitted may be different based on a composition of the active layer 154, and it is thus possible to identify light emitted by the light emitting diode chip 150 by irradiating light of the specific wavelength band to the active layer 154 even when no power is applied to the light emitting diode chip 150.

Referring back to FIG. 1, the light source unit 20 may be disposed on a transfer path on which the light emitting device package 100 is transferred by the transfer unit 10 and may emit the ‘measurement light L1’ of the specific wavelength to the front surface of the light emitting device package 100.

The ‘measurement light L1’ irradiated from the light source unit 20 may be determined based on a type of the light emitting diode chip included in the light emitting device package to be identified. For example, the ‘measurement light L1’, which emits the excitation light only from the green light emitting diode chip, may be irradiated to the light emitting device package 100 to check whether a light emitting diode chip of a different type (e.g., the yellow light emitting diode chip) is included in (and/or mixed) when the green light emitting diode chip is mounted on the electronic apparatus. In this case, the ‘measurement light L1’ may be ultraviolet light (UV) having a wavelength of about 400 nm.

Referring to FIG. 5, this configuration is described. For example, a first light emitting diode chip may emit excitation light G2 of a second wavelength λ2 when measurement light G1 of a first wavelength λ1 is irradiated thereto, and a second light emitting diode chip may emit excitation light G4 of a fourth wavelength λ4 when measurement light G3 of a third wavelength λ3 is irradiated thereto. In this case, the light source unit 20 may irradiate any one of the measurement light G1 of the first wavelength λ1 or the measurement light G3 of the third wavelength λ3 to the light emitting device package 100. Therefore, it is possible to determine the type of light emitting diode chip based on whether (or not) the measurement light induces an excitation light.

In addition, the light source unit 20 may irradiate the plurality of measurement lights having different wavelength bands to the light emitting device package 100 continuously or at time intervals. For example, the first measurement light, which induces the emittance of the excitation light only from the green light emitting diode chip, may be irradiated to the light emitting device package 100 and the second measurement light, which induces the emittance of the excitation light from the yellow light emitting diode chip, may then be irradiated to check whether the yellow light emitting diode chip is included when the green light emitting diode chip is mounted on the electronic apparatus.

The first camera 30 may be disposed on the transfer path of the light emitting device package 100 and may be adjacent to the light source unit 20. The first camera 30 may be disposed in a direction D1 toward the front surface of the light emitting device package 100, and transmit, to the control unit 60, a first image capturing a state in which the ‘measurement light L1’ of the light source unit 20 is irradiated to the light emitting device package 100. The first camera 30 may be synchronized with the light source unit 20 so that the light source unit 20 captures an image at the same time point at which the ‘measurement light L1’ is irradiated. In some example embodiments, a filter 40 blocking the ‘measurement light L1’ reflected from the surface of the light emitting device package 100 may be disposed between the first camera 30 and the light emitting device package 100.

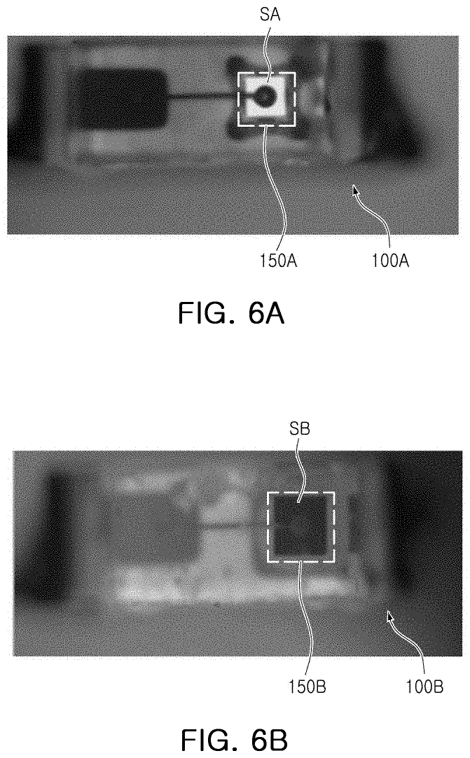

FIG. 6A is a front image of a normal light emitting device package 100A emitting the excitation light when the measurement light is irradiated thereto; and FIG. 6B is a front image of an abnormal light emitting device package 100B emitting no excitation light when the measurement light is irradiated thereto. It may be seen that the excitation light is emitted by an upper surface SA of a light emitting diode chip 150A mounted on the normal light emitting device package 100A. On the other hand, it may be seen that no excitation light is emitted by an upper surface SB of a light emitting diode chip 150B mounted on the abnormal light emitting device package 100B.

Referring to FIG. 1, the second camera 50 may be disposed on the transfer path of the light emitting device package 100 in a direction D2 and may face towards the lower surface of the light emitting device package 100, and transmit, to the control unit 60, a second image capturing the lower surface of the light emitting device package 100. As noted above, the lower surface of the light emitting device package 100 is a surface mounted on the electronic apparatus 200, and thus the control unit 60 may obtain position information of the light emitting device package 100 for accurately mounting the light emitting device package 100 on the mounting position 240 of the electronic apparatus 200, based on the image capturing the lower surface of the light emitting device package 100. The obtained position information may include the x-axis coordinate, y-axis coordinate, angle rotated with respect to a central axis, and/or the like of the light emitting device package 100.

The second camera 50 may be provided for capturing a state in which the light emitting device package 100 is picked up to the transfer unit 10, may be omitted in some example embodiments, or may be disposed separately from the electronic component mounting apparatus 1. In some example embodiments, the second camera 50 may be the same type of camera as that of the first camera 30.

The control unit 60 may image-process the first image transmitted from the first camera 30 to detect a region in which the light emitting diode chip 150 is captured in the first image and compare the image with the pre-stored reference image to identify whether the excitation light L2 is emitted by the light emitting diode chip 150. When determining that the light emitting device package 100 picked up to the transfer unit 10 is a suitable component, the control unit 60 may control the transfer unit 10 to mount the light emitting device package 100 picked up to the transfer unit 10 on the electronic apparatus 200. For example, a light emitting device package 100 may be considered suitable if the light emitting device package 100 includes the correct type (e.g., the right color) of light emitting device chip 150 for a design, and/or may be considered unsuitable if the light emitting device package 100 includes a broken light emitting device chip 150 and/or incorrect type of light emitting device chip 150 for the design. In addition, when determining that the light emitting device package 100 picked up to the transfer unit 10 is an unsuitable component, the control unit 60 may control the transfer unit 10 to discard and/or reposition the light emitting device package 100 picked up by the transfer unit 10; and/or when determining that the light emitting device package 100 picked up to the transfer unit 10 is a suitable component the control unit 60 may control the transfer unit 10 to place the light emitting device package 100 onto the electronic apparatus 200.

In addition, the control unit 60 may image-process the second image transmitted from the second camera 50 to obtain the position information of the light emitting device package 100. The control unit 60 may correct a position of the light emitting device package 100 while the transfer unit 10 mounts the light emitting device package 100 on the electronic apparatus 200, based on the obtained position information of the light emitting device package 100.

For example, the control unit 60 may be implemented as a processor such as a central processing unit (CPU), a graphic processing unit (GPU), a microprocessor, an application specific integrated circuit (ASIC), a field programmable gate arrays (FPGA), and/or the like. In addition, the control unit 60 may include a memory storing the image-processing of the first image and the second image and storing data used to control the transfer unit 10, the light source unit 20, the first camera 30, and/or the second camera 50.

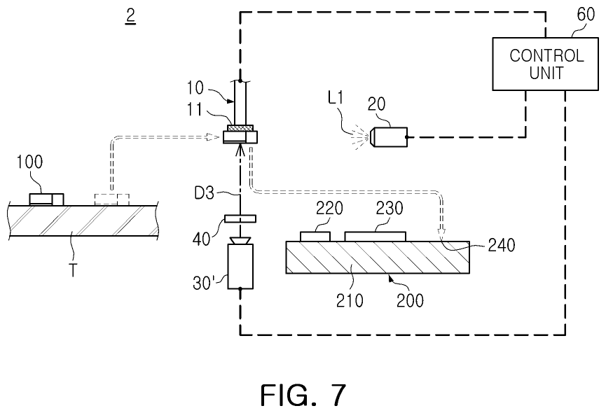

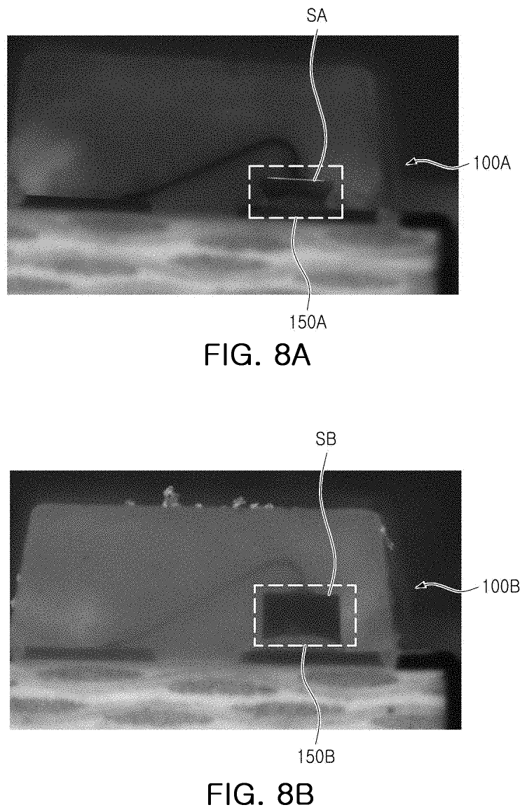

An electronic component mounting apparatus 2 according to some example embodiments is described with reference to FIGS. 7, 8A and 8B.

FIG. 7 is a view schematically illustrating the electronic component mounting apparatus according to some example embodiments of the present inventive concepts; FIG. 8A is a side image of the light emitting device package emitting the excitation light when the measurement light is irradiated thereto; and FIG. 8B is a side image of the light emitting device package emitting no excitation light when the measurement light is irradiated thereto.

When compared with the electronic component mounting apparatus 1 described above, the electronic component mounting apparatus 2 is different in that a first camera 30′ is disposed under the light emitting device package 100, and the type and position information of the light emitting device package 100 are obtained from an image captured by the first camera 30′. The other components may be denoted by the same reference numerals as those of the example of FIG. 1, and therefore the following description omits the detailed descriptions thereof.

The first camera 30′ may be disposed under the transfer path in which the light emitting device package 100 is transferred and may generate an image by capturing the lower surface of the light emitting device package 100 transferred by the transfer unit 10. The control unit 60 may image-process the image captured by the first camera 30′ to identify the type and position information of the light emitting device package 100, based on one image.

The image captured by the first camera 30′ may be an image capturing the lower surface of the light emitting device package 100, and it thus may be more difficult to check whether the excitation light is emitted by the light emitting device package 100 compared to the example of FIG. 1 described above. However, this disadvantage may be supplemented by a method such as increasing an amount of ‘measurement light L1’ emitted by the light source unit 20. The electronic component mounting apparatus 2 may obtain the type and position information of the light emitting device package 100 using one camera, which are respectively obtained using the first and second cameras 30 and 50 in the example described above. The electronic component mounting apparatus 2 may thus have a reduced manufacturing cost compared with the example described above with reference to FIG. 1.

FIG. 8A is an image of a lower portion of the light emitting device package 100A emitting excitation light when the measurement light is irradiated thereto; and FIG. 8B is an image of a lower portion of the abnormal light emitting device package 100B emitting no excitation light when the measurement light is irradiated thereto. It may be seen that the excitation light is emitted by the upper surface SA of the light emitting diode chip 150A mounted on the normal light emitting device package 100A. On the other hand, it may be seen that no excitation light is emitted by the upper surface SB of the light emitting diode chip 150B mounted on the abnormal light emitting device package 100B.

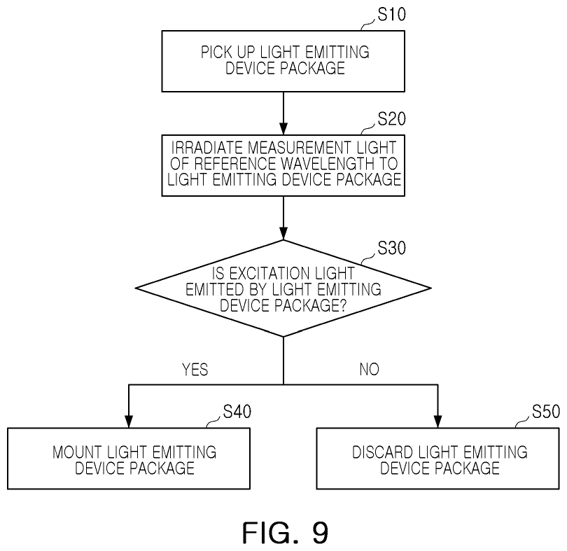

Next, the description describes an electronic component mounting method according to some example embodiments with reference to FIG. 9. FIG. 9 is a flowchart schematically illustrating the electronic component mounting method according to some example embodiment of the present inventive concepts. The electronic component mounting method of FIG. 9 may be a process using the electronic component mounting apparatus of FIG. 1 (and/or FIG. 7), and the description omits detailed descriptions of the components described with reference to FIG. 1. Example embodiment describes, as an example, a case where the excitation light of the second wavelength is emitted by the light emitting diode chip 150 of the light emitting device package 100 when the measurement light of the first wavelength is irradiated to the provided light emitting device package 100. In some example embodiments, the light emitting device package 100 emitting the excitation light when the measurement light of a reference wavelength is irradiated thereto may be determined as the suitable light emitting device package, and the light emitting device package 100 emitting no excitation light even when the measurement light is irradiated thereto may be determined as the unsuitable light emitting device package 100.

First, the light emitting device package 100 may be picked up (S10), e.g., by the transfer unit 10. The control unit 60 may control the transfer unit 10 to pick up the light emitting device package 100 and transfer the light emitting device package to the mounting position. The light emitting device package 100 at the time of the transfer may have a shape of the reel (e.g., attached to the tape T), but is not limited thereto.

Next, the measurement light (e.g., L1) of the reference wavelength may be irradiated to the light emitting device package 100 (S20). The control unit 60 may control the light source unit 20 to irradiate the measurement light to the front surface of the light emitting device package 100 on which the light emitting diode chip 150 is disposed. The measurement light may be light of the reference wavelength, emitting the excitation light in the suitable light emitting device package 100. For example, the ‘measurement light L1’ may be irradiated to the light emitting diode chip 150 disposed on the front surface of the light emitting device package 100. In some example embodiments, the ‘measurement light L1’ may be irradiated obliquely at a predetermined (or otherwise determined) angle with respect to the front surface of the light emitting device package 100.

Next, it may be determined whether the excitation light is emitted by the light emitting device package 100 (S30). The control unit 60 may control the first camera 30 to generate the first image capturing the front surface of the light emitting device package 100 at the time at which the measurement light is irradiated to the light emitting device package 100. In addition, the control unit 60 may image-process the first image to identify a region in which the light emitting diode chip 150 is disposed in the first image and identify whether the excitation light is captured in the identified region.

When it is confirmed that the excitation light is emitted by the light emitting device package 100, the control unit 60 may control the transfer unit 10 to mount the light emitting device package 100 on the electronic apparatus 200 (S40). On the other hand, when it is confirmed that no excitation light is emitted by the light emitting device package 100, the control unit 60 may control the transfer unit 10 to discard the light emitting device package 100 (S50).

As set forth above, the electronic component inspection apparatus according to the example embodiments of the present inventive concepts may identify the type of light emitting device package.

The electronic component mounting apparatus according to the example embodiments of the present inventive concepts may identify the type of light emitting device package before mounting the light emitting device package on the electronic apparatus.

While the example embodiments have been shown and described above, it will be apparent to those skilled in the art that modifications and variations could be made without departing from the scope of the present inventive concepts as defined by the appended claims.

What is claimed is:

1. An electronic component mounting apparatus comprising:
a transfer unit configured to transfer a light emitting device package to a printed circuit board;
a light source unit on a transfer path of the light emitting device package and configured to emit a measurement light of a first wavelength to a light emitting diode chip on the light emitting device package such that the light emitting diode chip emits excitation light of a second wavelength, longer than the first wavelength, when the light emitting device package is suitable;
a first camera on the transfer path of the light emitting device package and configured to capture an image of the light emitting device package; and
a control unit configured to determinine whether the light emitting device package is suitable or unsuitable based on whether the excitation light is captured in the image, and to control the transfer unit to mount the light emitting device package on the printed circuit board when the light emitting device package is determined to be suitable.

2. The electronic component mounting apparatus of claim 1, wherein
the light emitting device package has an upper surface, a lower surface opposite to the upper surface, and a front surface between the upper surface and the lower surface, the front surface including the light emitting diode chip, and
the transfer unit includes a picker configured to attach to the upper surface of the light emitting device package.

3. The electronic component mounting apparatus of claim 2, further comprising:
a second camera,
wherein the first camera is configured to face towards the front surface of the light emitting device package, and
the second camera is configured to face towards the lower surface of the light emitting device package.

4. The electronic component mounting apparatus of claim 3, wherein
the control unit is configured to determine whether the light emitting device package is suitable based on the image generated by the first camera capturing the front surface of the light emitting device package, and
the second camera is configured to generate a second image by capturing the lower surface of the light emitting device package.

5. The electronic component mounting apparatus of claim 4, wherein the control unit is configured to calculate position information of the light emitting device package based on the second image, and to correct a position of the light emitting device package based on the position information.

6. The electronic component mounting apparatus of claim 2, wherein the first camera is configured to generate the image by capturing the lower surface of the light emitting device package, and
the control unit is further configured to calculate position information of the light emitting device package based on the image.

7. The electronic component mounting apparatus of claim 1, wherein the control unit is configured to detect a region in which the light emitting diode chip is captured in the image, and to compare the image with a reference image to identify whether the excitation light is captured in the image.

8. The electronic component mounting apparatus of claim 1, wherein the control unit is configured to control the transfer unit to discard the light emitting device package when the light emitting device package is deterermined to be unsuitable.

9. The electronic component mounting apparatus of claim 1, further comprising:
a filter between the first camera and the light emitting device package, the filter configured to block light of the first wavelength reflected from the light emitting diode chip.

10. The electronic component mounting apparatus of claim 1, wherein
the light emitting diode chip includes a light emitting structure in which a first conductivity-type semiconductor layer, an active layer and a second conductivity-type semiconductor layer are sequentially stacked, and
the active layer is configured to emit the excitation light when the measurement light is irradiated thereto.

11. The electronic component mounting apparatus of claim 1, wherein the measurement light is ultraviolet light.

12. An electronic component mounting apparatus comprising:
a transfer unit configured to attach to an upper surface of a light emitting device package, and to transfer the light emitting device package to a printed circuit board;
a light source unit on a transfer path of the light emitting device package, and configured to irradiate measurement light towards a light emitting diode chip on a front surface of the light emitting device package such that the light emitting diode chip emits excitation light when the light emitting device package is suitable;
a camera configured to capture an image of the light emitting device package; and
a control unit configured to process the image to identify excitation light in the image and to control the transfer unit to mount the light emitting device package on the printed circuit board when the excitation light is identified.

13. The electronic component mounting apparatus of claim 12, wherein the camera is configured to face towards the front surface of the light emitting device package.

14. The electronic component mounting apparatus of claim 12, wherein the camera is configured to face towards a lower surface of the light emitting device package, opposite to the upper surface thereof.

15. The electronic component mounting apparatus of claim 12, wherein the control unit is configured to detect a region in which the light emitting diode chip is captured in the image, and to compare the image with a reference image to identify the excitation light in the image.

16. The electronic component mounting apparatus of claim 12, wherein the control unit is configured to control the transfer unit to discare the light emitting device package when the excitation light is not identified in the image.

17. The electronic component mounting apparatus of claim 12, further comprising:
a filter between the camera and the light emitting device package, the filter configured to block light reflected from the light emitting diode chip.

18. An electronic component inspection apparatus comprising:
a light source unit on a transfer path on which a light emitting device package is picked up and transferred, the light source unit configured to irradiate measurement light onto a front surface of the light emitting device package;
a camera configured to caputure an image of the light emitting device package; and
a control unit image-configured to process the image to identify excitation light, emitted from a light emitting diode chip on the front surface of the light emitting device when the light emitting diode chip is excited from the measurement light, and determining whether the light emitting device package is suitable or unsuitable based on an identification result.

19. The electronic component inspection apparatus of claim 18, wherein the light emitting diode chip includes a light emitting structure in which a first conductivity-type semiconductor layer, an active layer and a second conductivity-type semiconductor layer are sequentially stacked, and
the active layer emits the excitation light when the measurement light is irradiated thereto.

20. The electronic component inspection apparatus of claim 18, wherein the light source unit is configured such that the excitation light has a wavelength longer than a wavelength of the measurement light.
